(19) United States
(12) Patent Application Publication
(10) Pub. No.: US 2006/0170428 A1
(43) Pub. Date: Aug. 3, 2006

(54) Electrical safety cord

(76) Inventors: James Richter, Bethpage, NY (US); Roger M. Bradley, North Bellmore, NY (US); James N. Pearse, Libertyville, IL (US); James Pearse, Libertyville, IL (US)

Correspondence Address: PAUL J. SUTTON, ESQ., BARRY G. MAGIDOFF, ESQ.;GREENBERG TRAURIG, LLP, 200 PARK AVENUE, NEW YORK, NY, 10166, US

(21) Appl. No.: 11/210,650

(22) Filed: Aug. 24, 2005

Related U.S. Application Data
(60) Provisional application No. 60/614,650, filed on Sep. 30, 2004.

(51) Int. Cl. G01R 31/12

(52) U.S. Cl. 324/536

(57) ABSTRACT

An electric cable which can be used with a shock hazard protector to provide arc fault and ground fault protection at a minimum cost. The electric cable includes a first insulated conductor for coupling to a phase terminal of a protector, a second insulated conductor for coupling to a neutral terminal of the protector, and a third insulated conductor for coupling to a ground terminal. A separate or common conductive wrap surrounds the first and second insulated conductors but not the third conductor. The conductive wrap is for coupling to a sense terminal of the protector. The cable assures that a fault to ground, such as the energizing of the ground conductor, cannot occur before the fault energizes the conductive wrap. The cross-sectional shape of the electric cable can be substantially flat, substantially round or other shape.

This application claims priority of U.S. provisional application having Ser. No. 60/614,650 filed Sep. 30, 2004.

### BACKGROUND OF THE INVENTION

1. Field of the Invention

The present invention relates generally to electric cables and more specifically to an electric cable having three conductors which, when connected to a shock hazard protector, provides protection to both people and property against electric shock by providing both arc and ground fault protection.

2. Description of the Prior Art

The electrical extension cord in use today includes a plug, usually comprising three prongs, an electrical conducting cord typically comprising three insulated wires several feet in length and a terminal connector or receptacle for receiving one or more electrical plugs to power lamps, a television, household appliances, an air conditioner, etc. A grounded extension cord normally includes a plug having three prongs and a three conductor insulated wire cord where two conductors are utilized for phase and neutral and the third conductor is used as a common ground.

While extension cords provide many advantages, there are some disadvantages that are also associated with their use. For example, extension cords are often left underneath rugs where they are trampled upon, or they are pinched by doors and furniture which can lead to arcing or short circuiting which can cause a fire. Given the number of dangerous situations which can develop when using an extension cord with an electrical appliance, an extension or power cord which can be used in combination with an Immersion Detection Circuit Interrupter (IDCI) to provide arc and ground fault protection at a minimum cost is desired.

U.S. Pat. No. 5,642,248 assigned to Leviton Manufacturing Co., Inc. discloses an electrical extension cord where the insulated phase, neutral and ground conductors are surrounded by a braided sensing shield. The braided shield is electrically connected at the receptacle to the ground conductor and extends to the plug. Leakage current released from the conductors is collected in the shield and detected by a Ground Fault Circuit Interrupter (GFCI) to interrupt the flow of current to the load. The purpose of the shield is to capture any type of leakage current within the extension cord and transfer it to ground such that the GFCI may detect the current imbalance and interrupt the circuit.

Present day GFCI based leakage current detectors have several limitations. One such limitation is that of being a relatively expensive and complex device which requires, in addition to other components, the use of one or more toroidal transformers. In addition, presently available devices require that a ground be available at the outlet that the leakage current detector is plugged into. This may not always be the case in residential circuits, and some applications, such as in hospitals which require a floating ground.

What is needed is an extension cord or power cord which can be used with a circuit interrupter to provide arc fault and ground fault protection at a minimum cost.

### SUMMARY OF THE INVENTION

The present invention discloses an electric cable which can be used with a shock hazard protector to provide arc fault and ground fault protection at a minimum cost. The electric cable includes a first insulated conductor for coupling to a phase terminal of a protector, a second insulated conductor for coupling to a neutral terminal of the protector and a third insulated conductor for coupling to a ground terminal. A separate or common conductive wrap surrounds the first and second insulated conductors but not the third conductor. The cross-sectional shape of the electric cable can be substantially flat, substantially round or other shape. In one embodiment, the electric cable can be part of a conductor extension cord where one end of the electric cable is connected to a three conductor plug having ground fault protection circuitry and the second end connected to a 3 conductor receptacle. The conductive wrap assures that a fault to ground, such as the energizing of the ground conductor, cannot occur before the fault energizes the conductive wrap. In other words, because the conductive wrap surrounds the phase and neutral conductors, a ground fault first energizes the conductive wrap before the ground conductor is energized.

The foregoing has outlined, rather broadly, a preferred blending feature, for example, of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is a progressively sectionalized side view of an electric cable using separate conductive wraps in accordance with the principles of the invention;

FIG. 2 is a cross sectional view of another embodiment of an electric cable using a common conductive wrap; and

FIG. 3 is a schematic diagram of the electric cable of FIG. 2 coupled to a fault protector.

### DETAILED DESCRIPTION

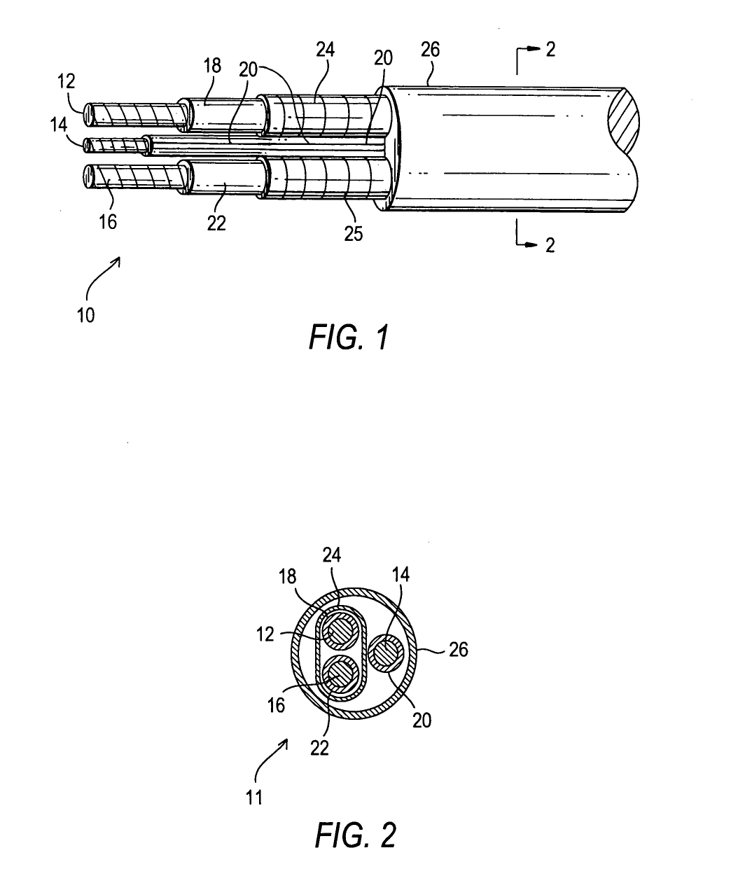

FIG. 1 illustrates an implementation of an electric cable 10 which can be used in combination with a shock hazard protector to provide protection for people and property. The cable 10 includes a first conductor 12 surrounded by insulating material 18, a second conductor 16 surrounded by insulating material 22 and a third conductor 14 surrounded by insulating material 20. The first conductor 12 is surrounded by a first conductive wrap 24 and the second conductor 16 is surrounded by a second conductive wrap 25. The third conductor 14 is not surrounded by a conductive wraps. A flexible cable jacket 26 of insulating material surrounds insulated conductor 14 and the insulated conductors 12, 16 and their conductive wraps 24, 25. The conductors 12, 14, 16 can be made of solid or stranded copper wire. The conductive wraps 24, 25 can be made of braided conductive shielding or other configurations of conductive material. In another embodiment, all three conductors 12, 14 and 16 can be surrounded by a single, common conductive wrap 24. The cross-sectional shape of the electric cable 10 can be substantially flat, substantially round or other shape and conductors 12, 14, 16 can be any standard wire gauge such as 10 AWG, 12 AWG, 14 AWG, 16 AWG, 18 AWG or other standard gauge. The electric cable 10 is compatible with standard SPT type cable (parallel jacketed thermoplastic cable) or other standard cables.

FIG. 2 illustrates another embodiment an extension cable according to the invention. As shown in FIG. 2, electric cable 11, instead of having separate conductive wraps 24, 25 as shown in FIG. 1 for cable 10, the cable 11 shown in FIG. 2 has a single, common conductive wrap 24 surrounding the first and second conductors 12, 16. In another embodiment, all three conductors 12, 14 and 16 can be surrounded by a single, common conductive wrap 24. The cross-sectional shape of the electric cable 11 can be substantially flat, substantially round or other shape and conductors 12, 14, 16 can be any standard wire gauge such as 10 AWG, 12 AWG, 14 AWG, 16 AWG, 18 AWG or other standard gauge. The electric cable 11 is compatible with standard SPT type cable (parallel jacketed thermoplastic cable) or other standard cables.

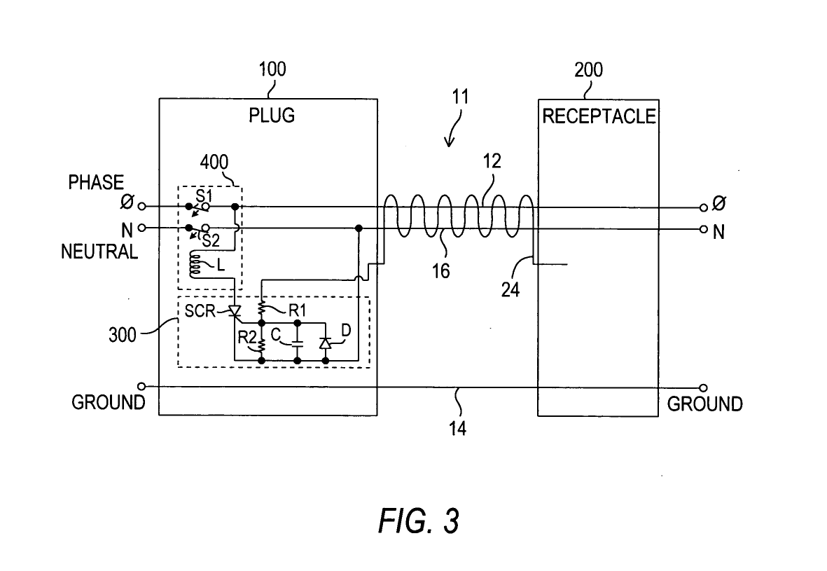

FIG. 3 of the present invention illustrates how the electric cable 11 here disclosed, when used as a power supply cord such as an extension cord, can be used as a safety cord by providing fault protection when used in conjunction with a shock hazard protector as disclosed in U.S. Pat. No. 4,709,293. Referring to FIG. 3 of the present invention, the cable 11 assures that a fault condition (i.e., fault to ground, such as the energizing of the ground conductor 14) cannot occur before the fault energizes the conductive wrap 24 which will cause the circuitry 300, 400 to operate and disconnect the AC power source from the cable 11. The arrangement here disclosed allows for the use of the less expensive circuit 300 with a grounded three conductor cable thus eliminating the need for the differential current transformer normally required for a ground fault protection device.

The cable 11 is a three wire (12, 16 and 14) cable (phase, neutral and ground conductor) with a conductive wrap 24 connected between the three conductor plug 100 and the three conductor receptacle 200. In particular, the first end of the conductive wrap 24 is connected to the control circuit 300 at the plug 100 and the second end is supported by receptacle 200 and electrically isolated from the conductors 12, 16. The plug end of the first conductor 12 (phase) is connected to the phase terminal of the plug 100 through switch S1 and the receptacle end of the first conductor 12 is connected to the phase terminal of the receptacle 200. Likewise, the plug end of the second conductor 16 (neutral) is connected to the neutral terminal of the receptacle 200 through switch S2 and the receptacle end of the second conductor 16 is connected to the neutral terminal of the receptacle 200. The plug end of the ground conductor 14 is connected to the ground terminal of the plug 100 and the receptacle end of the ground conductor 14 is connected to the ground terminal of the receptacle 200.

Control circuit 300 comprises a solid state switching control circuit and includes a first resistor R1 connected in-line between the gate of a silicon controlled rectifier SCR and the plug end of the conductive wrap 24. Resistor R1 limits the current applied to the gate of the SCR. In addition, control circuit 300 includes a parallel network comprising resistor R2, capacitor C and diode D connected between the gate and cathode of the SCR. These components provide a measure of noise immunity and protection against damage across the gate to cathode junction of the SCR.

Interrupter circuit 400 comprises an electromechanical interrupting circuit and includes an energizing coil L and a first and second contact or switch S1, S2 connected in-line with the first and second electrical conductors 12, 16, respectively. Switches S1 and S2 are responsive to the flow of current through energizing coil L and are closed when such current is not flowing. In response to the flow of such current they switch from the normally closed position to the ground fault (shock hazard) condition open position. One end of energizing coil L is connected to the first electrical conductor 12 and the other end thereof is connected to the anode of the SCR. The cathode of the SCR is operatively connected to the second electrical conductor 16.

In the normal mode of operation, that is, in the absence of a fault condition along the cable (i.e., conductor 12 or 16 is not energizing the conductive wrap 24), the SCR is in the normally non-conducting state. In this state, the switches S1 and S2 are in the normally closed position, thereby providing a path for current to flow through the cable. In a fault condition, conductive wrap 24 is energized which causes the gate of the SCR to be energized. In response thereto, the SCR switches from the normally non-conducting state to the conducting state, thereby providing a path for current to flow through the energizing coil L causing switches S1 and S2 to switch from the normally closed position to the fault condition open position and thus operatively disconnecting the AC source from the cable. Exemplary values for the circuit illustrated in FIG. 3 are as follows: R1—2000 ohms, R2—1000 ohms, C1 microfarads, D-1N4004, SCR-2N5064.

While there have been shown and described and pointed out the fundamental novel features of the invention as applied to the preferred embodiments, it will be understood that various omissions and substitutions and changes of the form and details of the structures and circuits illustrated and in their operation may be made by those skilled in the art without departing from the spirit of the invention.

What is claimed is:

1. An electric cable comprising:
a first conductor surrounded by insulating material adapted to be coupled a shock hazard protector;
a second conductor surrounded by insulating material adapted to be coupled to the shock hazard protector;
conductive wrap surrounding said first insulated conductor and second insulated conductor, wherein the conductive wrap is adapted to be coupled to a sense terminal of the shock hazard protector;
a third conductor surrounded by insulating material; and
an insulating jacket surrounding the first insulated conductor, second insulated conductor, third insulated conductor and the conductive wrap.

2. The electric cable of claim 1 wherein said first and second conductors are surrounded with a common conductive wrap.

3. The electric cable of claim 1 wherein said first and second conductors are surrounded by separate conductive wraps.

4. The electric cable of claim 1 wherein said conductive wrap surrounding said first and second conductors; and
a third conductor surrounded by insulating and not surrounded by a conductive wrap are all surrounded by a cable jacket.

5. The electric cable of claim 1 wherein the first conductor is a solid or stranded electrical conductor.

6. The electric cable of claim 1 wherein the second conductor is a solid or a stranded electrical conductor.

7. The electric cable of claim 1 wherein the third conductor is a solid or a stranded electrical conductor.

8. The electric cable of claim 1 wherein the conductive wrap is a braided conductive shielding.

9. The electric cable of claim 1 wherein the third conductor is not surrounded by conductive wrap.

10. The electric cable of claim 1 wherein the electric cable has a substantially flat cross-sectional shape.

11. The electric cable of claim 1 wherein the electric cable has a substantially round cross-sectional shape.

12. The electric cable of claim 1 wherein the first conductor is adapted to be connected to the phase terminal of a shock hazard protector and the second conductor is adapted to be connected to the neutral terminal of a shock hazard protector.

13. The electric cable of claim 1 wherein the first conductor is adapted to be connected to the neutral terminal of a shock hazard protector and the second conductor is adapted to be connected to the phase terminal of the shock hazard protector.
